(19) United States
(12) Patent Application Publication
(10) Pub. No.: US 2009/0127707 A1
(43) Pub. Date: May 21, 2009

(54) SEMICONDUCTOR DEVICE AND METHOD FOR MANUFACTURING THE SAME

(75) Inventor: Keisuke SATO, Kanagawa (JP)

Correspondence Address: YOUNG & THOMPSON, 209 Madison Street, Suite 500, ALEXANDRIA, VA, 22314, US

(73) Assignee: NEC ELECTRONICS CORPORATION, Kanagawa (JP)

(21) Appl. No.: 12/269,300

(22) Filed: Nov. 12, 2008

(30) Foreign Application Priority Data
Nov. 20, 2007 (JP) 2007-300281

(51) Int. Cl. H01L 23/48; H01L 21/60

(52) U.S. Cl. 257/737; 438/109; 257/E23.01

(57) ABSTRACT

A semiconductor device having good radiation performance is provided. The semiconductor device is provided with a substrate having one surface in which external connection terminals are formed. The semiconductor device includes the substrate having a wiring layer; a semiconductor chip which is mounted on the one surface of the substrate; the external connection terminals formed on the one surface of the substrate so as to be located along the perimeter of the semiconductor chip; and a conductive part formed on the one surface and having a melting point higher than that of the external connection terminals and electrically insulated from the wiring layer.

### BACKGROUND OF THE INVENTION

1. Field of the Invention

The present invention relates to a semiconductor device and a method for manufacturing the same, and in particular to a semiconductor device having a substrate with external connection terminals formed on one surface thereof, and a method for manufacturing the same.

2. Description of the Related Art

Active development is under way in semiconductor devices having a plurality of external connection terminals on one surface, such as BGAs (Ball Grid Arrays). In connecting such a semiconductor device to a motherboard, such as a circuit board, it has been an important point to uniform the height of the external connection terminals in order to ensure reliability of the semiconductor device after establishing connection. If the semiconductor is connected with a tilt, the height of the external connection terminals is varied from the connected area. Such variation in the height of the connection terminals can vary the contact resistance between the terminals. Further, those areas in which the connection terminals have large height may suffer from disconnection after being used for a long time. In this way, connecting a semiconductor device in a state of being tilted resultantly causes a significant deterioration in the connection reliability.

Japanese Patent Laid-Open Publication No. 2005-129752 discloses a technique for uniforming the height of external connection terminals. FIG. 16 is a schematic cross-sectional view illustrating a configuration of a semiconductor device 10. The semiconductor device 10 includes a wiring board 11, as well as external connection terminals 12 and a spacer 13, which are formed on one surface of the wiring board 11. A semiconductor chip 14 is mounted on the other side of the wiring board 11.

Electronic parts 15 are mounted on the one surface of the wiring board 11 so as to be located within the spacer 13. When the wiring board 11 is installed so that the one surface of the wiring board 11 will be opposed to one surface of a circuit board (not shown), such as a motherboard, the distance between the wiring board 11 and the motherboard will be restricted by the spacer 13. In this way, the height of the external connection terminals 12 which are provided on the same surface as the spacer 13 can be kept constant.

As is represented by cell phones recently, there has been a demand for thinner semiconductor devices. In order to keep up with the demand, it has been desired to reduce the gap between a wiring board and a motherboard as much as possible. However, a smaller gap between a wiring board and a motherboard may raise a problem of heat radiation from the electronic parts 15 in Japanese Patent Laid-Open Publication No. 2005-129752, which are mounted on the one surface of the wiring board 11. The spacer 13 in which the electronic parts 15 are provided is formed of an insulating material, such as a resin. In general, insulating materials have low heat conductivity, and thus heat radiation from the electronic parts 15 is prevented from being sufficiently performed, which may cause failure in the electronic parts 15. Thus, the technique disclosed in Japanese Patent Laid-Open Publication No. 2005-129752 has left room for improvement in the heat radiation performance of the semiconductor device.

### SUMMARY

According to the present invention, a semiconductor device is provided, including: a substrate having a wiring layer; a semiconductor chip mounted on one surface of the substrate; external connection terminals formed on the one surface so as to be located along a perimeter of the semiconductor chip; and a conductive part formed on the one surface, the conductive part having a melting point higher than that of the external connection terminals and being electrically insulated from the wiring layer.

According to the present invention, a method for manufacturing a semiconductor device is provided, including: forming a conductive part on one surface of a substrate having a wiring layer in a manner that the conductive part is electrically insulated from the wiring layer; mounting a semiconductor chip on the one surface of the substrate; and forming external connection terminals on the one surface of the substrate, the external connection terminals having a melting point which is lower than that of the conductive part.

In the semiconductor device and a method for manufacturing the same related to the present invention, the substrate having the wiring layer has one surface which is provided with the external connection terminals and the conductive part having a melting point higher than that of the external connection terminals and electrically insulated from the wiring layer. Thus, the conductive part plays a roll of a heat sink and radiates heat generated from the semiconductor chip, whereby heat radiation performance of the semiconductor device is enhanced.

According to the present invention, the semiconductor device can be provided, which has the substrate with one surface thereof being formed with the external connection terminals and has good heat radiation performance.

### BRIEF DESCRIPTION OF THE DRAWINGS

FIGS. 1A and 1B are schematic diagrams illustrating a semiconductor device according to a first embodiment of the present invention;

FIG. 2 is a schematic diagram illustrating the semiconductor device according to the first embodiment of the present invention;

FIGS. 3A to 3C are schematic diagrams illustrating a method for manufacturing the semiconductor device according to the first embodiment of the present invention;

FIGS. 4A and 4B are schematic diagrams illustrating a semiconductor device according to a second embodiment of the present invention;

FIGS. 5A and 5B are schematic diagrams illustrating a semiconductor device according to a third embodiment of the present invention;

FIGS. 6A and 6B are schematic diagrams illustrating the semiconductor device according to the third embodiment of the present invention;

FIGS. 7A to 7D are schematic diagrams illustrating a method for manufacturing the semiconductor device according to the third embodiment of the present invention;

FIGS. 8A and 8B are schematic diagrams illustrating a semiconductor device according to a fourth embodiment of the present invention;

FIGS. 9A and 9B are schematic diagrams illustrating a semiconductor device according to a fifth embodiment of the present invention;

FIGS. 10A and 10B are schematic diagrams illustrating the semiconductor device according to the fifth embodiment of the present invention;

FIGS. 11A and 11B are schematic diagrams illustrating a semiconductor device according to a sixth embodiment of the present invention;

FIGS. 12A and 12B are schematic diagrams illustrating a semiconductor device according to a seventh embodiment of the present invention;

FIGS. 13A and 13B are schematic diagrams illustrating the semiconductor device according to the seventh embodiment of the present invention;

FIGS. 14A to 14D are schematic diagrams illustrating a method for manufacturing the semiconductor device according to the seventh embodiment of the present invention;

FIGS. 15A and 15B are schematic diagrams illustrating a semiconductor device according to an eighth embodiment of the present invention; and

FIG. 16 is a schematic cross-sectional view illustrating prior art related to the present invention.

### DETAILED DESCRIPTION OF THE PREFERRED EMBODIMENTS

### First Embodiment

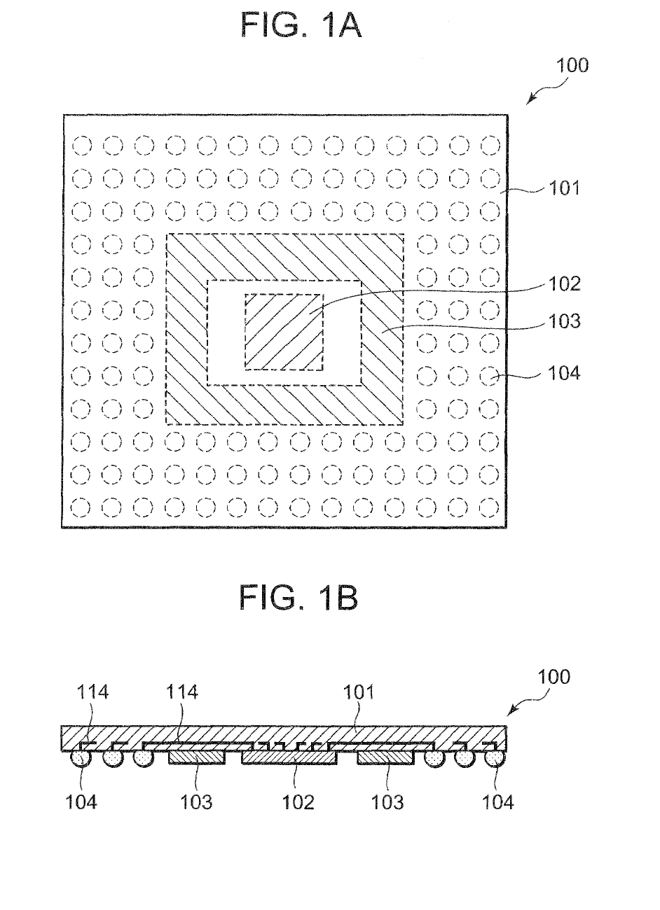

FIGS. 1A and 1B are schematic diagrams illustrating a semiconductor device 100 illustrating a first embodiment of the present invention. FIG. 1A is a top plan, and FIG. 1B is a cross-sectional view.

As shown in FIGS. 1A and 1B, the semiconductor device 100 includes a substrate (hereinafter referred to as a “wiring board”) 101 (first substrate) having a wiring layer 114 therein, as well as a semiconductor chip 102, a conductive part 103 and external connection terminals 104, which are mounted on one surface of the wiring board 101. In FIG. 1A, the wiring layer 114 in the wiring board 101 is omitted from indication. In the subsequent figures as well, indication of the wiring layer is appropriately omitted. The conductive part 103 has a melting point higher than that of the external connection terminals 104, and is electrically insulated from the wiring layer 114. The semiconductor chip 102 is mounted on the wiring board 101 by being flip-chip connected thereto, for example. The semiconductor chip 102 and the external connection terminals 104 are electrically connected through the wiring layer 114.

As shown in FIG. 1A, the external connection terminals 104 are arranged on the outside of the semiconductor chip 102, the outside corresponding to the perimeter of the wiring board 101. The conductive part 103 having a shape of a frame is arranged between a region where the semiconductor chip 102 is formed and a region where the external connection terminals 104 are formed to enclose the semiconductor chip 102. Thus, the conductive part 103 plays a roll of a heat sink. Therefore, the heat from the semiconductor chip 102 can be more effectively radiated by arranging the conductive part 103 in the vicinity of the semiconductor chip 102. A plurality of lines of the conductive part 103 may be formed, being spaced apart from each other with a gap.

For example, Sn—Ag—Cu alloy may be used for the external connection terminals 104 (melting point is 221° C. with an Ag content of 3 wt (weight) % and a Cu content of 0.5 wt %). Metal, such as Cu or Al, may be used for the conductive part 103, which metal has a higher melting point than the material used for the external connection terminal 104.

A semiconductor chip formed with a logic circuit or an ASIC (Application Specific Integrated Circuit), for example, may be used for the semiconductor chip 102. A semiconductor package including the semiconductor chip 102 may be provided instead of the semiconductor chip 102.

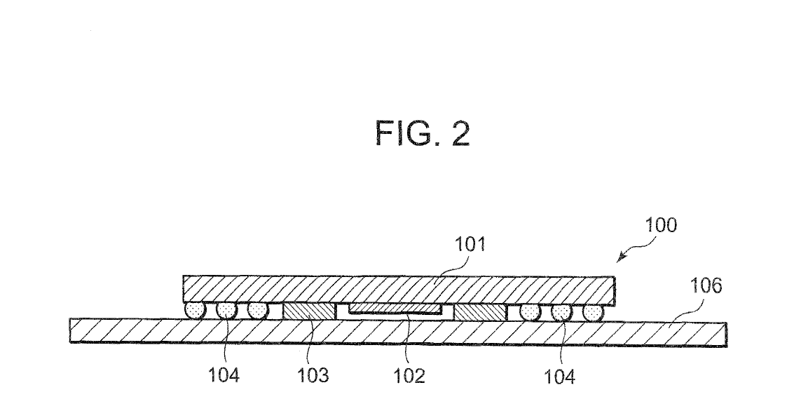

As shown in FIG. 2, connection between the semiconductor device 100 and a motherboard 106 is established so that the one surface of the wiring board 101 is located opposed to one surface of the motherboard 106. Accordingly, the distance between the wiring board 101 and the motherboard is restricted by the conductive part 103, whereby the height of the external connection terminals 104 formed on: the same surface as the conductive part 103 can be kept constant. Further, the melting point of the conductive part 103 is higher than that of the external connection terminals 104. Therefore, the heat treatment temperature in establishing connection with the motherboard 106 is set to a level which is equal to or higher than the melting point of the material used for the external connection terminals 104 but lower than the melting point of the conductive part 103. In this way, the height of the external connection terminals 104 can be kept constant without damaging the shape of the conductive part 103.

Also, since the conductive part 103 is in contact with the one surface of the motherboard 106, a heat radiation path can be formed, through which the heat generated from the semiconductor chip 102 flows to the side of the motherboard through the conductive part 103. Thus, the heat radiation path can be ensured extending from the conductive part 103 to the motherboard to enhance the heat radiation performance of the semiconductor device 100.

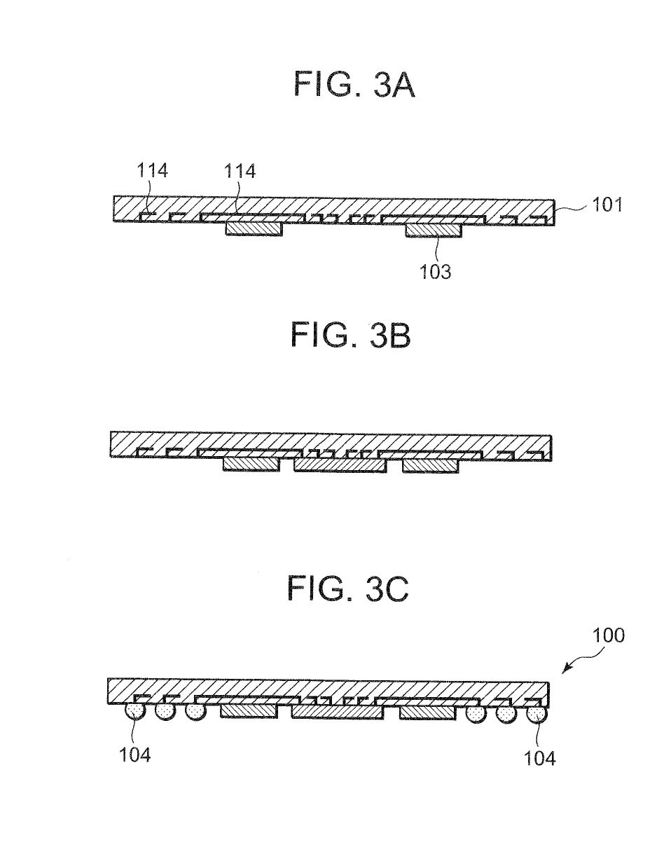

Referring to FIGS. 3A to 3C, hereinafter is described a method for manufacturing the semiconductor device 100.

FIGS. 3A to 3C are schematic cross-sectional views illustrating steps of manufacturing the semiconductor device 100.

As shown in FIG. 3A, the conductive part 103 is stuck onto the one surface of the wiring board 101 having the wiring layer 114 by means of an adhesive agent, for example. The conductive part 103 may be made of a material, such as metal of Cu or Al, having a higher melting point than the material used for the external connection terminals 104. The conductive part 103 is formed so as to be insulated from the wiring layer 114 in the wiring board 101. In particular, the conductive part 103 is formed in a manner of avoiding lands (not shown) for the external connection terminals, which lands are connected to the wiring layer 114. The conductive part 103 may have a shape of a frame to enclose the semiconductor chip 102. The conductive part 103 may be attached using reflow treatment. The temperature used for the reflow treatment is higher than that used for forming other components, such as the external connection terminals 104, because the conductive part 103 is made of a material of high melting point. However, since the reflow treatment of the conductive part 103 is carried out prior to the formation of other components, such as the external connection terminals 104, no thermal damage can be caused on other components, such as the external connection terminals 104. Then, as shown in FIG. 3B, the semiconductor chip 102 is mounted on the one surface of the wiring board 101. The semiconductor chip 102 can be mounted using a known flip-chip connection method. Then, as shown in FIG. 3C, the external connection terminals 104, such as solder balls, are formed.

### Second Embodiment

The present embodiment has a configuration in which the semiconductor device described in the first embodiment is mounted on a circuit board, such as a motherboard.

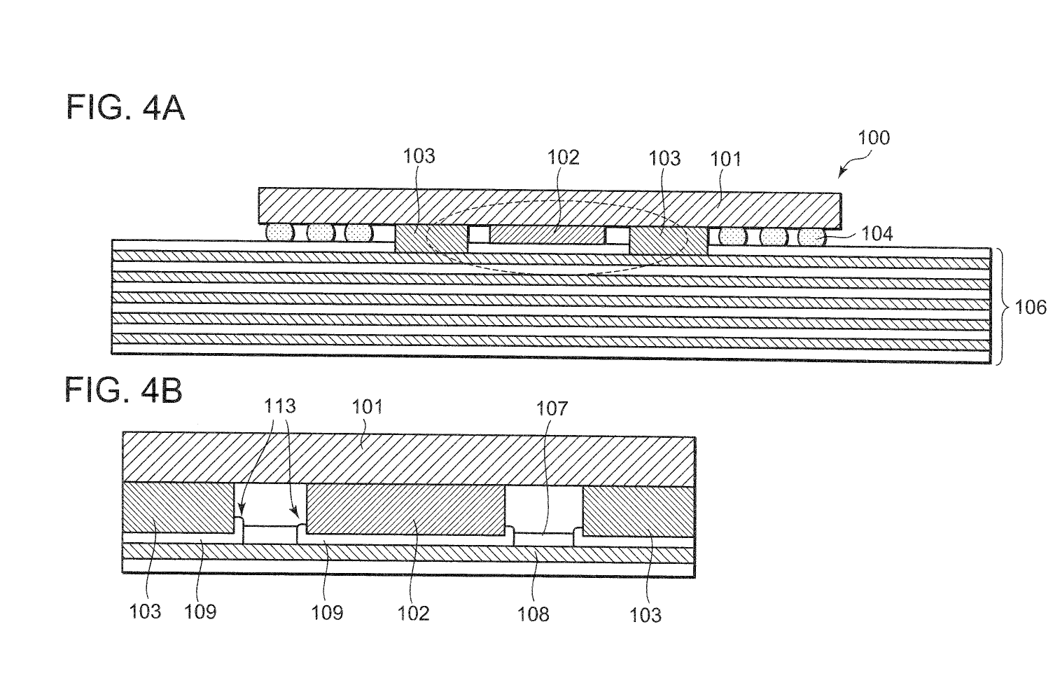

FIGS. 4A and 4B are schematic cross-sectional views illustrating a configuration in which the semiconductor device 100 described in the first embodiment is mounted on a substrate (second substrate), such as the motherboard 106. The motherboard 106 includes a plurality of wiring layers 108.

As shown in FIGS. 4A and 4B, the lower surface of the semiconductor chip 102 (the surface opposite to the surface through which the semiconductor chip 102 is mounted on the wiring board 101) and a portion (lower surface) of the conductive part 103 are in contact with the motherboard 106. In particular, the height of the conductive part 103 is adapted to be larger than that of the external connection terminals 104. As shown in FIG. 4B, a surface insulation layer 107 is removed from regions in the one surface of the motherboard 106, where the semiconductor chip 102 and the conductive part 103 are in contact with the motherboard 106, to form recessed portions 113 in which a first wiring layer 108 counting from the one surface of the motherboard is exposed. In the recessed portions 113, the lower surfaces of the semiconductor chip 102 and the conductive part 103 can be connected to the exposed first wiring layer 108 through a film made such as of a resin 109 having heat radiation performance. With this configuration, the heat generated from the semiconductor chip 102 can be effectively radiated to the side of the motherboard 106 in a direct manner or through the conductive part 103. Thus, a heat radiation path is formed extending from the semiconductor chip 102 or the conductive part 103 to the motherboard 106 to further enhance the heat radiation performance of the semiconductor device 100. The resin 109 having heat radiation performance may have either conductivity or insulating properties. For example, if the lower surface of the semiconductor chip 102 and the conductive part 103 are short-circuited to ground with the motherboard 106 serving as the ground, conductive pastes, such as an Ag-based paste or a silicon-based conductive paste, may be used. Also, if potential is provided, insulating pastes, such as of silicone, may be used. In the present embodiment, both of the conductive part 103 and the semiconductor chip 102 are connected to the wiring layer 108 of the motherboard 106. Alternative to this, only one of the conductive part 103 and the semiconductor chip 102 may be connected to the wiring layer 108. In other words, the semiconductor chip 102 may not be in contact with the motherboard 106.

The semiconductor device 100 is mounted on the motherboard 106 so that the one surface of the substrate 101 is located opposed to the one surface of the motherboard 106. Therefore, the distance between the substrate 101 and the motherboard 106 is restricted by the conductive part 103, whereby the height of the external connection terminals 104 can be kept constant. The material used for the conductive part 103 has a melting point higher than that of the external connection terminals 104. Therefore, the heat treatment temperature used in establishing connection with the motherboard is set to a level equal to or higher than the melting point of the material used for the external connection terminals 104 but lower than the melting point of the conductive part 103. In this way, the height of the external connection terminals 104 can be kept constant without damaging the shape of the conductive part 103. For example, when Sn—Ag—Cu having the melting point of 221° C. used in the first embodiment is used as the external connection terminals 104, and the heat treatment temperature is 250° C. in connecting the semiconductor device 100 to the motherboard 106, the conductive part 103 formed such as of Cu or Al whose melting point is higher than the heating treatment temperature will not be damaged on its shape. Thus, owing to the conductive part 103, the height of the external connection terminals 104 can be kept constant.

### Third Embodiment

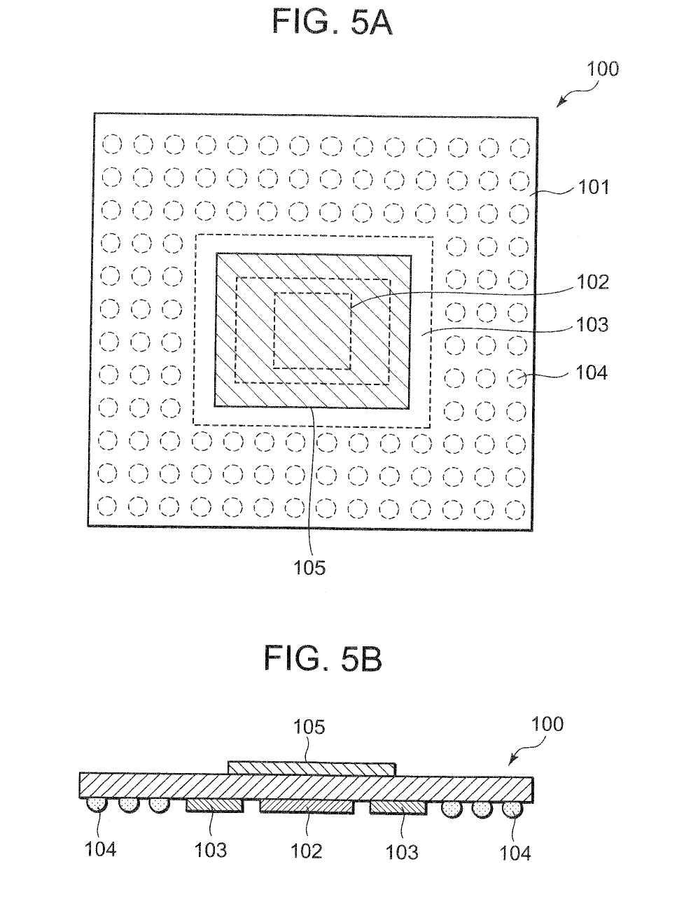

FIGS. 5A and 5B are schematic diagrams illustrating a semiconductor device 100 according to a third embodiment of the present invention. The present embodiment is different from other embodiments in that a second semiconductor chip is provided at the other surface of a wiring board 101. FIG. 5A is a top plan, and FIG. 5B is a cross-sectional view.

As shown in FIGS. 5A and 5B, the semiconductor device 100 includes the wiring board 101 (first substrate), as well as a first semiconductor chip 102 (corresponding to the “semiconductor chip” in the first and second embodiments), a conductive part 103 and external connection terminals 104, which are mounted on one surface of the wiring board 101, and a second semiconductor chip 105 mounted on the other surface of the wiring board 101. The first and second semiconductor chips 102 and 105 are mounted on the wiring board 101 using, for example, a flip-chip connection method. Although the indication of a wiring layer is omitted from the wiring board 101, it should be appreciated that the first and second semiconductor chips 102 and 105 are electrically connected to the external connection terminals through the wiring layer. The conductive part 103 has a higher melting point than the external connection terminals 104, and is electrically insulated from the wiring layer in the wiring board 101.

As shown in FIG. 5A, the external connection terminals 104 of the present embodiment are arranged on the outside of the first semiconductor chip 102, the outside corresponding to the perimeter of the wiring board 101. The conductive part 103 has a shape of a frame and is arranged between a region where the first semiconductor chip 102 is formed and a region where the external connection terminals 104 are formed to enclose the first semiconductor chip 102. Thus, since the conductive part 103 plays a roll of a heat sink, the heat from the first semiconductor chip 102 can be more effectively radiated by arranging the conductive part 103 in the vicinity of the first semiconductor chip 102.

For example, an alloy such as of Sn—Ag—Cu may be used for the external connection terminals 104 (melting point is 221° C. with an Ag content of 3 wt % and a Cu content of 0.5 wt %). Metal, such as Cu or Al, having a higher melting point than the material used for the external connection terminals may used for the conductive part 103.

A chip formed with a logic circuit or an ASIC (Application Specific Integrated Circuit), for example, may be used for the first semiconductor chip 102. A chip formed with a memory circuit may be used for the second semiconductor chip 105. Semiconductor packages including the first and second semiconductor chips 102 and 105 may be provided instead of the first and second semiconductor chips 102 and 105, respectively.

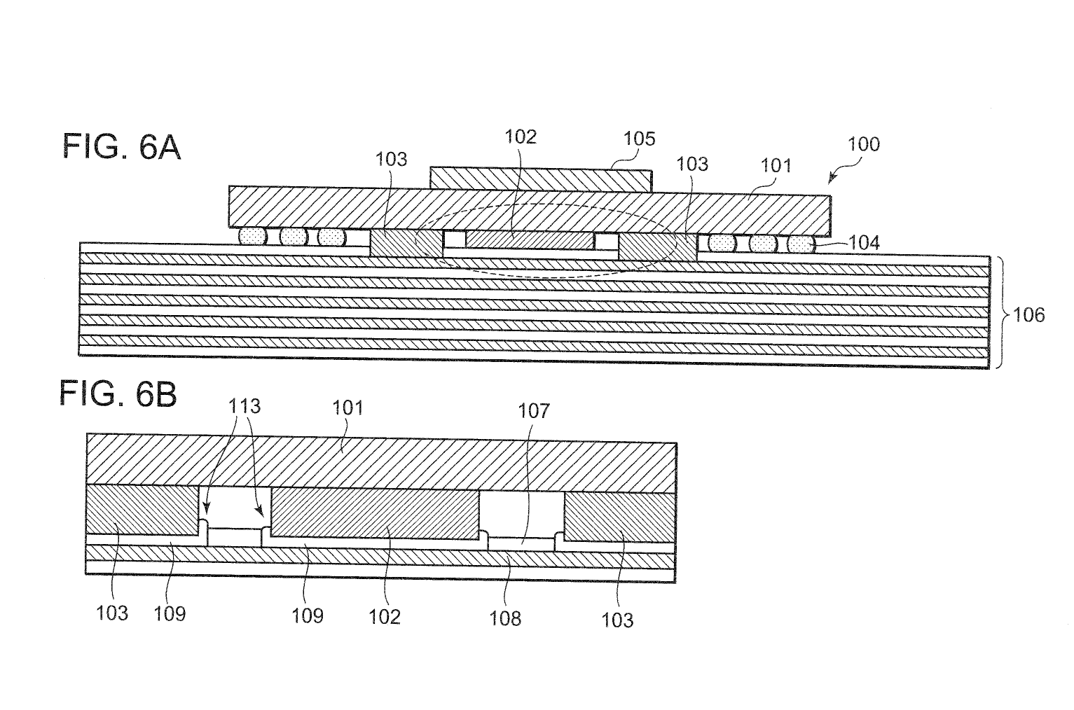

FIGS. 6A and 6B are schematic cross-sectional views illustrating a configuration in which the semiconductor device 100 is mounted on the motherboard 106. The semiconductor device 100 is mounted so that the one surface of the wiring board 101 faces the motherboard 106. Therefore, the distance between the wiring board 101 and the motherboard 106 is restricted by the conductive part 103. As a result, the height of the external connection terminals 104 which are formed on the same surface as the conductive part 103 can be kept constant.

The lower surface of the first semiconductor chip 102 (the surface opposite to the surface through which the first semiconductor chip 102 is mounted on the wiring board 101) is in contact with the motherboard 106. Further, as shown in FIG. 6B, the motherboard 106 has regions which are in contact with the first semiconductor chip 102 and the conductive part 103. In the regions, a surface insulation layer 107 is removed to form recessed portions 113, with a first wiring layer 108 being exposed therein. The lower surfaces of the first semiconductor chip 102 and the conductive part 103 are connected to the exposed first wiring layer 108 through a film such as a resin 109 having heat radiation performance. In this way, the heat generated from the semiconductor chip 102 is effectively radiated to the side of the motherboard 106 in a direct manner or through the conductive part 103, similar to the second embodiment. Thus, with the formation of a heat radiation path from the semiconductor chip 102 or the conductive part 103 to the motherboard 106, the heat radiation performance of the semiconductor device 100 can be further enhanced In the present embodiment, both of the conductive part 103 and the semiconductor chip 102 are connected to the wiring layer 108 of the motherboard 106. Alternative to this, either one of the conductive part 103 and the semiconductor chip 102 may be connected to the wiring layer 108. In other words, the semiconductor chip 102 may not be in contact with the motherboard 106.

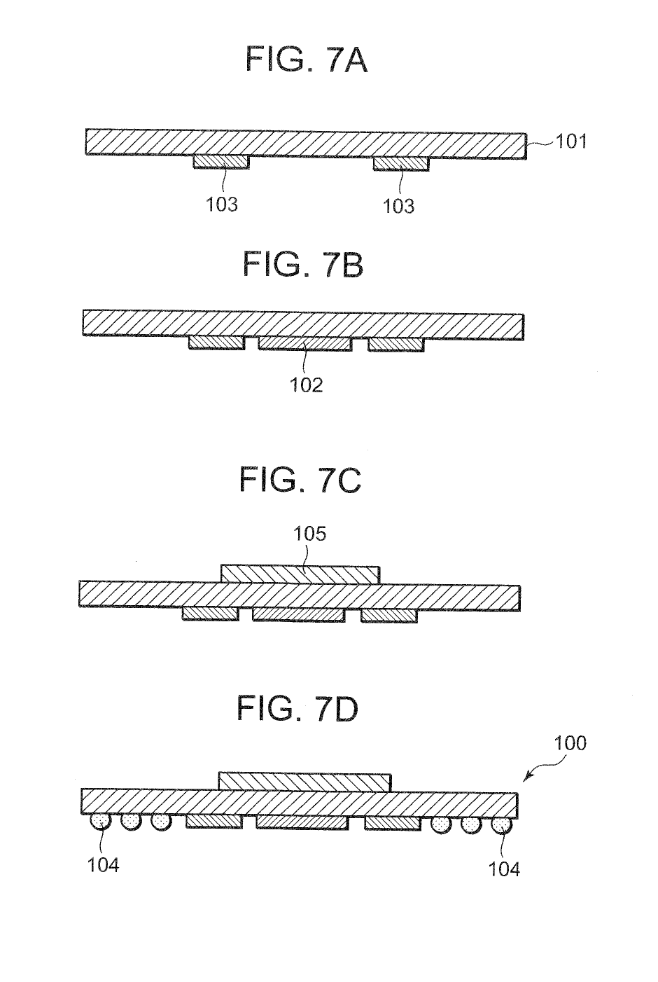

Referring now to FIGS. 7A to 7D, hereinafter is described a method for manufacturing the semiconductor device 100. FIGS. 7A to 7D are schematic cross-sectional views illustrating steps of manufacturing the semiconductor device 100.

As shown in FIG. 7A, the conductive part 103 is stuck onto the one surface of the wiring board 101 by means of an adhesive agent, for example. A material, such as Cu or Al, having a higher melting point than the material used for the external connection terminals 104 may be used for the conductive part 103. The conductive part 103 is formed in a manner of being insulated from a wiring layer (not shown) in the wiring board 101. Specifically, the conductive part 103 is provided in a manner of avoiding lands (not shown) for the external connection terminals, which lands are connected to the wiring layer. The conductive part 103 may be attached by reflow. The temperature used for the reflow temperature is higher than that used for forming other components, such as the external connection terminals 104, because the conductive part 103 is made of a material of high melting point. However, since the reflow treatment of the conductive part 103 is carried out prior to the formation of other components, such as the external connection terminals 104, no thermal damage can be caused on other components, such as the external connection terminals 104. Then, as shown in FIG. 7B, the first semiconductor chip is mounted on the one surface of the wiring board 101. The first semiconductor chip 102 can be mounted using a known flip-chip connection method. Then, as shown in FIG. 7C, the second semiconductor chip 105 is mounted on the other surface of the wiring board 101. The second semiconductor chip 105 can be mounted using a known flip-chip connection method, similar to the first semiconductor chip. In the present embodiment, the second semiconductor chip 105 is mounted after mounting the first semiconductor chip 102. This is because the size of the first semiconductor chip 102 is smaller than that of the second semiconductor chip 105, and thus because the second semiconductor chip 105 can be mounted in a state where warpage of the substrate 101 has been minimized by having the first semiconductor chip 102 of smaller size mounted first. Thus, if the size of the second semiconductor chip 105 is smaller than that of the first semiconductor chip 102, the order of mounting may be reversed from that of the present embodiment. That is, the first semiconductor chip 102 may be mounted after mounting the second semiconductor chip 105. Subsequently, as shown in FIG. 7D, the external connection terminals 104, such as solder balls, are formed.

The semiconductor device 100 is mounted on the motherboard 106 so that the one surface of the substrate 101 faces the motherboard 106. Since the distance between the wiring board 101 and the motherboard 106 is restricted by the conductive part 103, the height of the external connection terminals 104 can be kept constant. The material used for the conductive part 103 has a melting point higher than that of the external connection terminals 104. Therefore, the heat treatment temperature used in establishing connection with the motherboard is set to a level equal to or higher than the melting point of the material used for the external connection terminals 104 but lower than the melting point of the conductive part 103. In this way, the height of the external connection terminals 104 can be kept constant without damaging the shape of the conductive part 103.

### Fourth Embodiment

The present embodiment is different from other embodiments in that a radiator plate (second conductive part) 110 is further formed on the other surface of a wiring board 101.

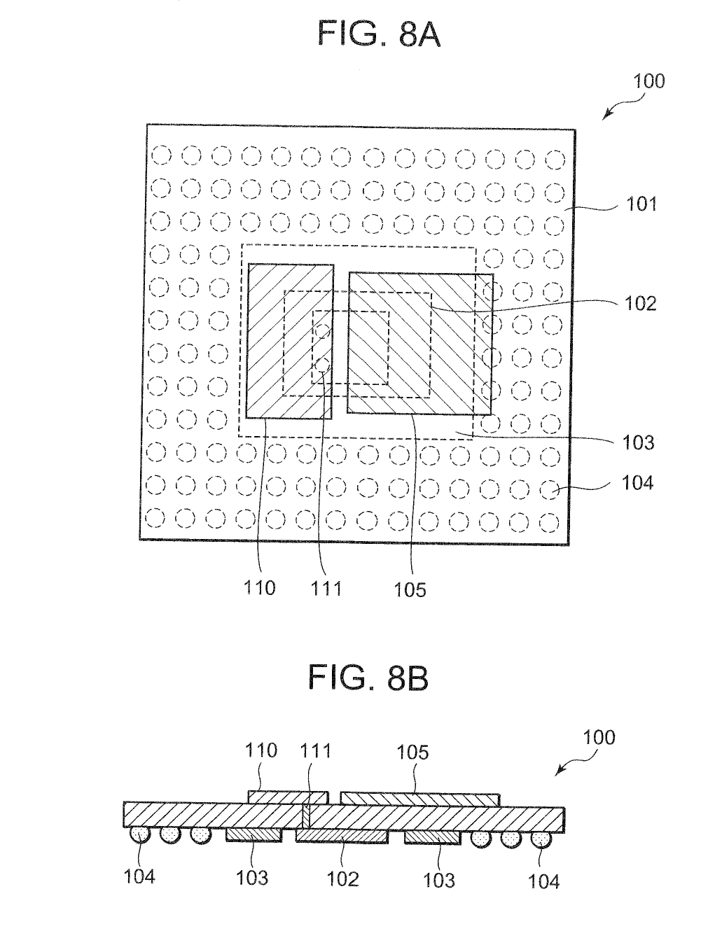

FIGS. 8A and 8B are schematic diagrams illustrating a semiconductor device 100 according to the present embodiment. FIG. 8A is a top plan and FIG. 8B is a cross-sectional view.

As shown in FIGS. 8A and 8B, the semiconductor device 100 includes the wiring board 101, as well as a first semiconductor chip 102, a conductive part (first conductive part) 103 and external connection terminals 104, which are mounted on one surface of the wiring board 101, and a second semiconductor chip 105 and the radiator plate (second conductive part) 110, which are mounted on the other side of the wiring board 101. The radiator plate 110 can be formed so as to be insulated from a wiring layer (not shown) in the wiring board 101. The radiator plate 110 can be stuck onto the wiring board 101 using an adhesive agent, for example. Vias (third conductive part) 111 are formed in the wiring board 101 so as to pass through the board in the thickness direction. Rear surfaces of the first semiconductor chip 102 and the radiator plate 110 (the surfaces through which the first semiconductor chip 102 and the radiator plate 109 are mounted on the wiring board 101) are connected to the vias. The vias 111 are formed avoiding the wiring layer (not shown) in the wiring board 101. Each of the vias 111 is formed by providing a through hole in the wiring board 101 and embedding, for example, metal, such as Cu, and an electrically conductive resin in the through hole. The number of vias 111 may be one, or two or more. As shown in FIG. 8A, since the second semiconductor chip 105 is provided avoiding the radiator plate 110, the center of the second semiconductor chip 105 in plan is offset from that of the first semiconductor chip 102. In the present embodiment, the external connection terminals 104 are located on the outside of the first semiconductor chip 102, the outside corresponding to the perimeter of the wiring board 101. The conductive part 103 has a shape of a frame and is located between a region where the first semiconductor chip 102 is formed and a region where the external connection terminals 104 are formed to enclose the first semiconductor chip 102. Thus, since the conductive part 103 plays a roll of a heat sink, the heat from the first semiconductor chip 102 can be more effectively radiated by arranging the conductive part 103 in the vicinity of the first semiconductor chip 102.

For example, an alloy, such as Sn—Ag—Cu, may be used for the external connection terminals 104. Metal, such as Cu or Al, having a higher melting point than the material used for the external connection terminals 104 may be used for the conductive part 103. Similarly, metal such as Cu or Al, having a higher melting point than the material used for the external connection terminals 104 may be used for the radiator plate 110.

A chip in which a logic circuit or an ASIC is formed, for example, may be used as the first semiconductor chip 102. Also, a chip in which a memory circuit is formed may be used as the second semiconductor chip 105. Semiconductor packages including the first and second semiconductor chips 102 and 105 may be provided instead of the first and second semiconductor chip 102 and 105, respectively.

The first semiconductor chip 102 is connected to the rear surface of the radiator plate 110 through the vias (third conductive part) 111 that pass through the wiring board 101. Thus, a heat radiation path is formed extending from each via 112 to the radiator plate 110 to the heat caused buy the first semiconductor chip 102, by which the heat radiation performance of the semiconductor device 100 can be further enhanced. Preferably, the via 111 is connected to a macro-region where power consumption is large, in particular, in an element forming region formed in the first semiconductor chip 102. This is because such a region where power consumption is large may also have a large calorific power. The macro-region having large power consumption may include, for example, SerDes (SERializer/DESerializer) operating at high speed such as for Ethernet® or PCI-Express, or serial ATA (Advanced Technology Attachment) and Xaui. Although the present embodiment is configured so that the heat of the first semiconductor chip 102 is radiated through the vias 111, the conductive part 103 and the second semiconductor chip 105 may be removed from the configuration.

### Fifth Embodiment

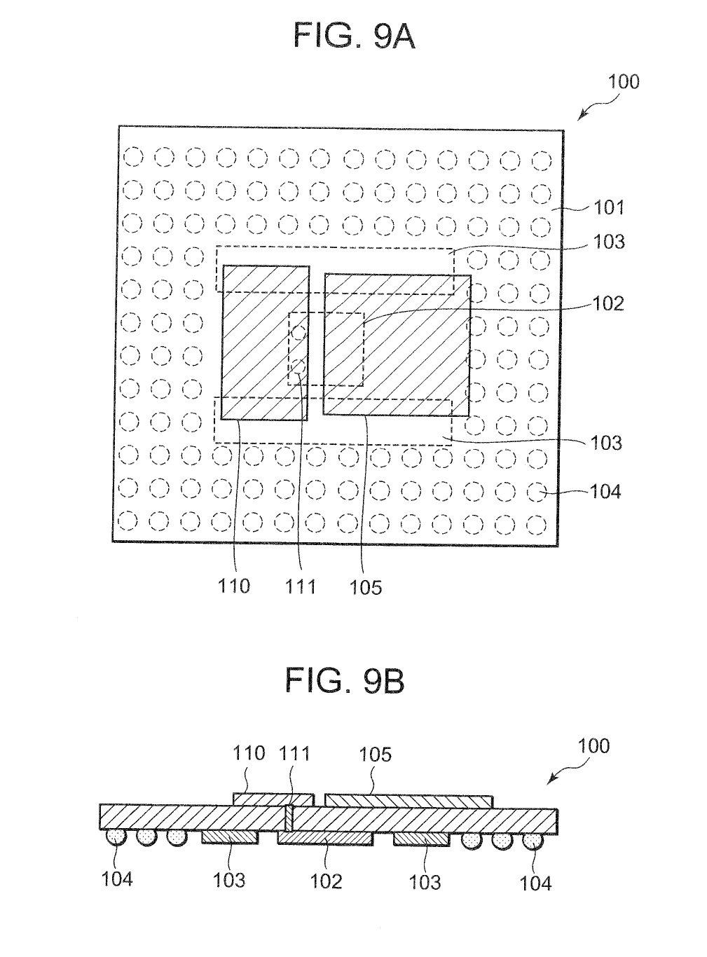

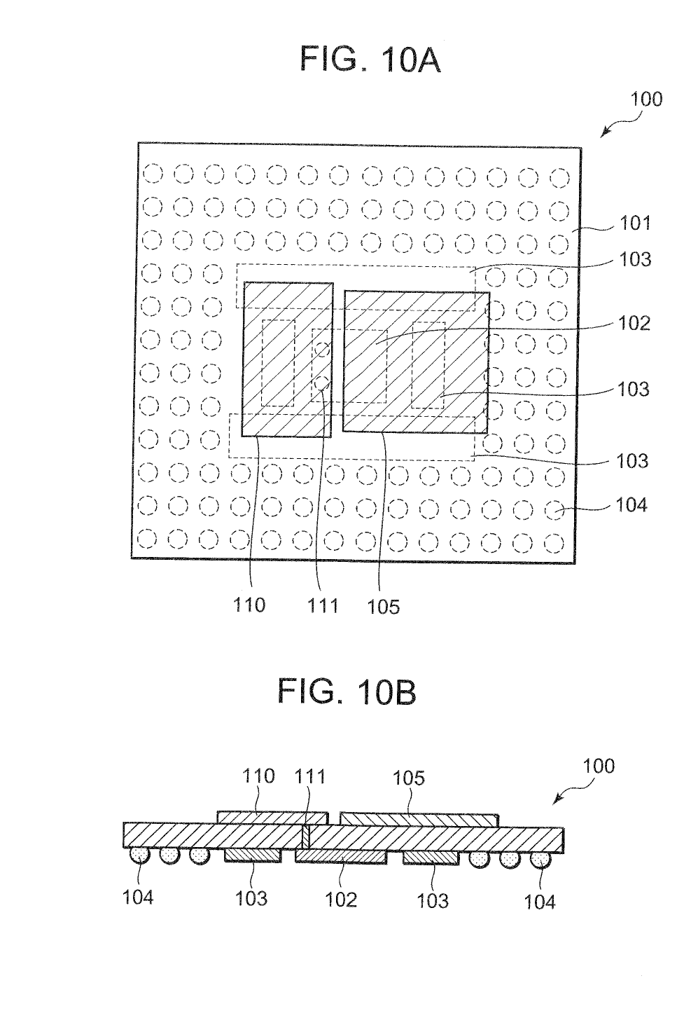

The present embodiment is different from other embodiments in that the present embodiment has a conductive part 103 which is differently shaped and arranged from other embodiments. FIGS. 9A, 9B, 10A and 10B are schematic diagrams each illustrating a semiconductor device 100 according to the present embodiment.

FIGS. 9A and 9B show an example in which the conductive part 103 is formed into a linear shape and arranged outside of each of two sides of a first semiconductor chip 102, which sides are opposed to each other. FIG. 9A is a schematic top plan and FIG. 9B is a schematic cross-sectional view.

FIGS. 10A and 10B show an example in which the linear conductive part 103 is arranged outside of each of four sides of the first semiconductor chip 102. FIG. 10A is a schematic top plan and FIG. 10B is a schematic cross-sectional view.

### Sixth Embodiment

In the present embodiment, a conductive part 103 is formed into a linear shape and a plurality of the linear conductive parts 103 are arranged.

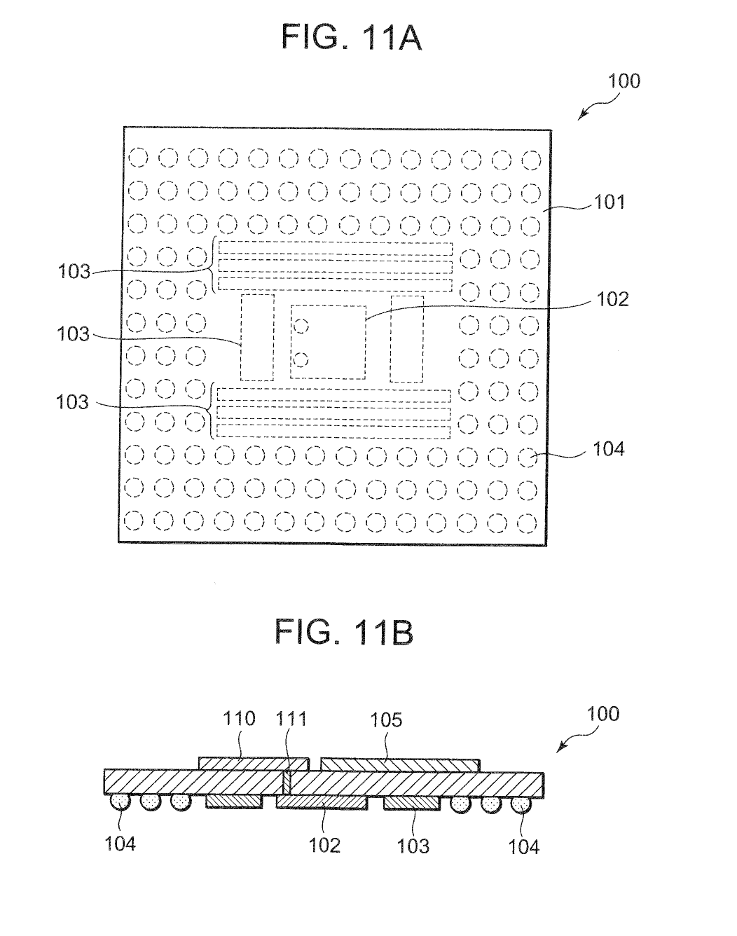

In the configuration shown in FIGS. 11A and 11B, the linear conductive parts 103 are arranged outside of the respective four sides of a first semiconductor chip 102. As to two opposed sides among the four sides, for example, a plurality of lines of the conductive parts 103 are arranged outside the two opposed sides, with a gap being provided therebetween. Since the plurality of lines of the conductive parts 103 are formed outside the two opposed sides with a gap being provided therebetween, heat radiation performance of the semiconductor chip 102 may be further enhanced comparing with the case of forming a single line of the conductive part 103. In FIG. 11A, indication of the second semiconductor chip 102 and a radiator plate 110 is omitted.

### Seventh Embodiment

The present embodiment is different from other embodiments in that a conductive part 103 is formed into the shape of a ball.

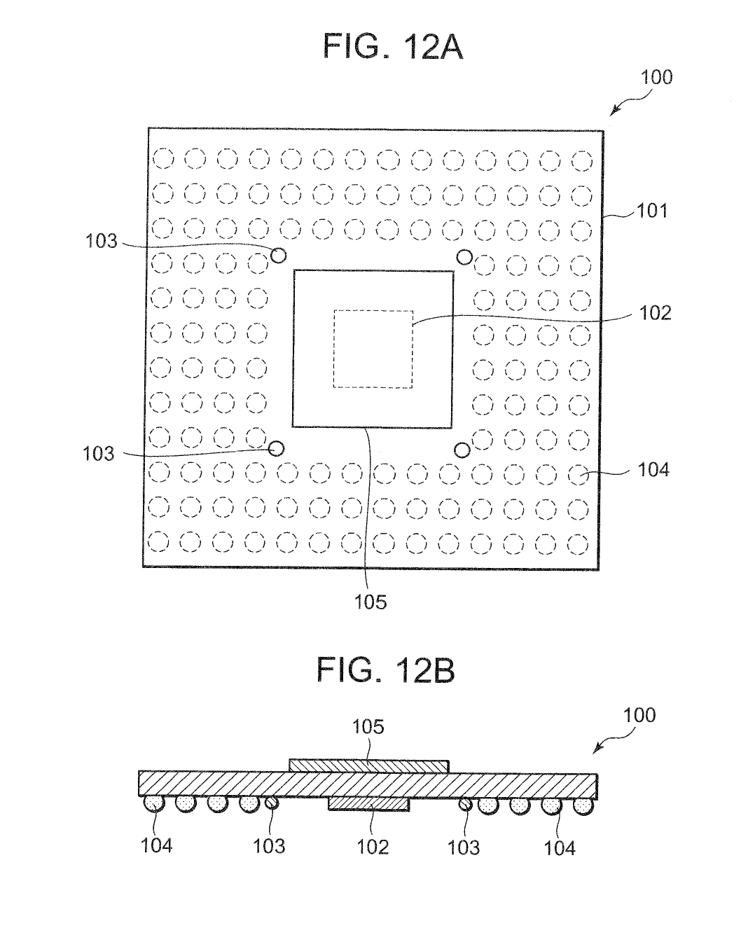

As shown in FIGS. 12A and 12B, a semiconductor device 100 includes a wiring board 101, as well as a first semiconductor chip 102, the balled conductive parts 103 and external connection terminals 104, which are mounted on one surface of the wiring board 101, and a second semiconductor chip 105 mounted on the other side of the wiring board 101. The conductive parts 103 have a higher melting point than the external connection terminals 104, and are electrically insulated from a wiring layer (not shown) in the wiring board 101. The first or second semiconductor chip 102 or 105 and the external connection terminals 104 are electrically connected to each other through the wiring layer (not shown) in the wiring board 101. As shown in FIG. 12A, the present embodiment is configured so that the external connection terminals 104 are arranged on the outside of the first semiconductor chip 102, the outside corresponding to the perimeter of the wiring board 101.

The conductive part 103 is arranged between a region where the first semiconductor chip 102 is formed and a region where the external connection terminals 104 are formed to enclose the first semiconductor chip 102. In the present embodiment, the balled conductive parts 103 are arranged at four points which are located near respective corner portions of the first semiconductor chip, but alternatively the location may be near respective sides of the chip. Also, the number of the conductive parts 103 may preferably be at least three in order to steadily restrict the distance between the wiring board 101 and the motherboard 106. Increase in the number of the conductive parts 103 may resultantly enhance the heat radiation performance of the first semiconductor chip 102.

For example, an alloy, such as Sn—Ag—Cu (melting point is 221° C. with an Ag content of 3 wt % and a Cu content of 0.5 wt %) may be used for the external connection terminals 104. A material having a higher melting point than the material used for the external connection terminals 104 may be used for the conductive parts 103. For example, Sn (melting point: about 232° C.), Pb (melting point: about 328° C.) or an alloy of these materials may be used.

A chip in which a logic circuit or an ASIC is formed may be used for the first semiconductor chip 102. Also, a chip in which a memory circuit is formed may be used for the second semiconductor chip 105. Semiconductor packages including the first and second semiconductor chips 102 and 105 may be provided instead of the first and second semiconductor chip 102 and 105, respectively. The balled conductive parts 103 may be arranged on the outside of the external connection terminals 104, the outside corresponding to the perimeter of the wiring board 101, or may be provided within a region where the external connection terminals 104 are formed.

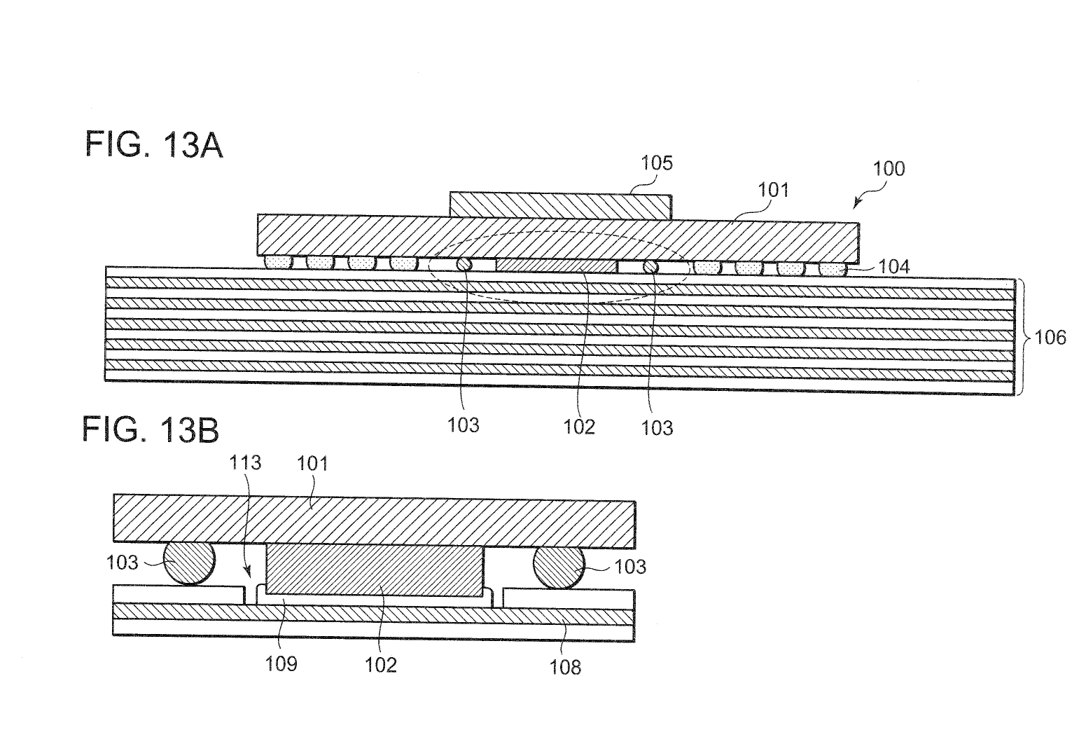

As shown in FIG. 13A, the semiconductor device 100 is mounted in such a way that the one surface of the wiring board 101 faces the motherboard 106. Therefore, the distance between the wiring board 101 and the motherboard 106 is restricted by the conductive parts 103. Thus, the height of the external connection terminals 104 which are formed on the same surface as the conductive parts 103 can be kept constant.

As shown in FIG. 13B, the lower surface of the first semiconductor chip 102 (the surface opposite to the surface through which the semiconductor chip is 102 is mounted on the wiring board 101) may be in contact with the motherboard 106. A surface insulation layer 107 is removed from a region in the motherboard 106, with which the first semiconductor chip 102 is in contact to form recessed portions 113, with a first wiring layer 108 being exposed therein. The lower surface of the first semiconductor chip 102 is connected to the exposed first wiring layer 108 through a film such as a resin 109 having heat radiation performance. In this way, the heat generated from the first semiconductor chip 102 is directly radiated to the side of the motherboard 106 to further enhance the heat radiation performance. Also, as in the second embodiment, the conductive parts 103 may be connected to the wiring layer 108 of the motherboard 106 through a film such as the resin 109 having heat radiation performance, in a manner similar to the first semiconductor chip.

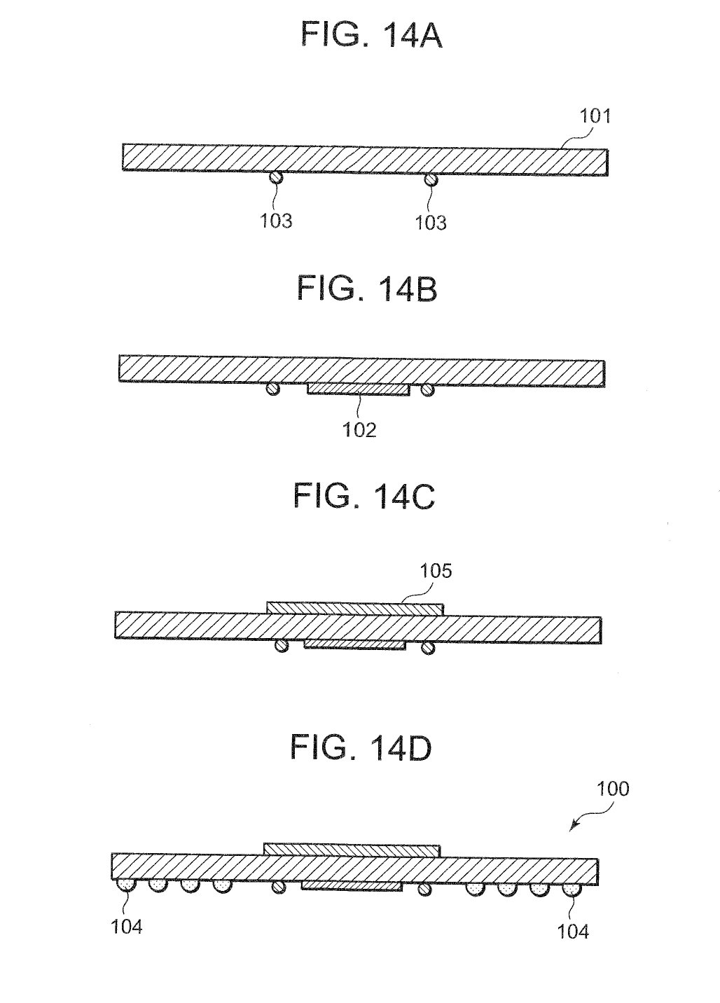

Referring now to FIGS. 14A to 14D, hereinafter is explained a method for manufacturing the present semiconductor device 100. FIGS. 14A to 14D are schematic cross-sectional views illustrating steps of the method for manufacturing the semiconductor device 100.

As shown in FIG. 14A, the balled conductive parts 103 are formed on the one surface of the wiring board 101. The material that can be used for the conductive parts 103 is a material, such as Sn or Pb, or an alloy of these materials, having a higher melting point than the material used for the external connection terminals 104. Each of the conductive parts 103 is formed on a land (not shown) insulated from the wiring layer (not shown) in the wiring board 101. Then, as shown in FIG. 14B, the first semiconductor chip 102 is mounted on the one surface of the wiring board 101. The first semiconductor chip 102 can be mounted using a known flip-chip connection method. Subsequently, as shown in FIG. 14C, the second semiconductor chip 105 is mounted on the other surface of the substrate 101. The second semiconductor chip 105 can be mounted using a known flip-chip connection method, similar to the manner of mounting the first semiconductor chip 102. In the present embodiment, the second semiconductor chip 105 is mounted after mounting the first semiconductor chip 102. This is because the size of the first semiconductor chip 102 is smaller than that of the second semiconductor chip 105, and thus because the second semiconductor chip 105 can be mounted in a state where warpage of the substrate 101 is minimized by having the first semiconductor chip 102 of smaller size mounted first. Thus, if the size of the second semiconductor chip 105 is smaller than that of the first semiconductor chip 102, the order of mounting may be reversed from that of the present embodiment. That is, the first semiconductor chip 102 may be mounted after mounting the second semiconductor chip 105. Subsequently, as shown in FIG. 14D, the external connection terminals 104 made of Sn—Ag—Cu or the like having a melting point of 221° C., for example, may be formed on the one surface of the wiring board 101.

The semiconductor device 100 is mounted on the motherboard 106 (see FIG. 13B) so that the one surface of the wiring board 101 faces the motherboard 106. In this case, the distance between the substrate 101 and the motherboard 106 is restricted by the conductive parts 103, whereby the height of the external connection terminals 104 can be kept constant. As described above, the material used for the conductive parts 103 has a higher melting point than the external connection terminals 104. Therefore, the heat treatment temperature used in establishing connection with the motherboard 106 is set to a level equal to or higher than the melting point of the material used for the external connection terminals 104 but lower than the melting point of the conductive part 103. In this way, the height of the external connection terminals 104 can be kept constant without damaging the shape of the conductive part 103. For example, when an Sn—Ag—Cu alloy having a melting point of 221° C. is used for the external connection terminals 104 and the treatment temperature used in connecting the substrate 101 to the motherboard 106 is 225° C., no damage may be caused in the shape of the conductive parts 103 made of a material such as Sn or Pb, or an alloy of Sn and Pb, having a melting point higher than 221° C. As a result, the height of the external connection terminals 104 can be kept constant.

### Eighth Embodiment

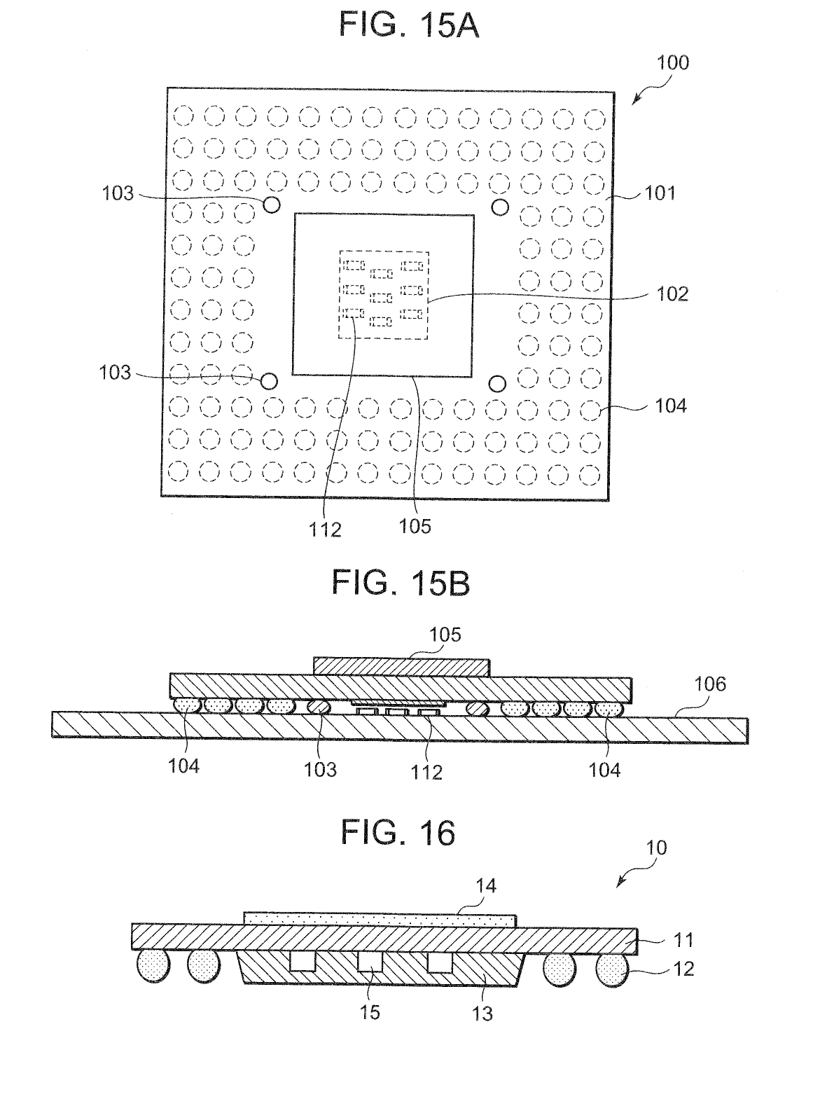

The present embodiment has a configuration in which electronic parts 112, such as capacitors and resistors, are provided on the motherboard 106, and the lower surface of a first semiconductor chip 102 is distanced from the electronic parts 112. FIGS. 15A and 15B are schematic diagrams illustrating a semiconductor device 100 according to the present embodiment. FIG. 15A is a top plan and FIG. 15B is a cross-sectional view. In FIG. 15A, indication of a motherboard 106 is omitted.

As shown in FIGS. 15A and 15B, the electronic parts 112, such as capacitors and resistors, may be mounted on the motherboard 106. In this case, the first semiconductor chip 102 can be arranged, with its lower surface (the surface opposite to the surface through which the semiconductor chip 102 is mounted on the wiring board 101) being distanced from the upper surfaces of the electronic parts 112. With this configuration, freedom degree of design can be enhanced in, for example, arranging the electronic parts 112 on the motherboard 106.

What is claimed is:

1. A semiconductor device comprising:
a substrate having a wiring layer;
a semiconductor chip mounted on one surface of the substrate;
external connection terminals formed on the one surface so as to be located along a perimeter of the semiconductor chip; and
a conductive part formed on the one surface, the conductive part having a melting point higher than that of the external connection terminals and being electrically insulated from the wiring layer.

2. The semiconductor device according to claim 1, wherein the conductive part is formed between a region where the external connection terminals are formed and a region where the semiconductor chip is formed.

3. The semiconductor device according to claim 1, wherein the conductive part has a shape of a frame and is formed so as to enclose the perimeter of the semiconductor chip.

4. The semiconductor device according to claim 1, wherein the conductive part is formed into at least one linear conductive part.

5. The semiconductor device according to claim 3, wherein the conductive part is formed into a plurality of lines of the linear conductive parts.

6. The semiconductor device according to claim 1, wherein the conductive part is formed into a plurality of balled conductive parts.

7. The semiconductor device according to claim 1, wherein the substrate is a first substrate, and one surface of the first substrate and one surface of a second substrate are arranged so as to be opposed to each other.

8. The semiconductor device according to claim 7, wherein a height of the conductive part is larger than that of the external connection terminals.

9. The semiconductor device according to claim 7, wherein:
the second substrate has a wiring layer; and
the semiconductor chip has a surface connected to the wiring layer of the second substrate, the surface being opposite to the surface through which the semiconductor chip is mounted on the first substrate.

10. The semiconductor device according to claim 7, wherein:
the second substrate has a wiring layer; and
a portion of the conductive part is connected to the wiring layer of the second substrate.

11. The semiconductor device according to claim 9, wherein:
a recessed portion in which the wiring layer is exposed, is formed on one surface of the second substrate; and
the recessed portion permits establishment of connection therein between a surface opposite to the surface through which the semiconductor chip is mounted on the first substrate and the wiring layer of the second substrate, or between the portion of the conductive part and the wiring layer of the second substrate.

12. The semiconductor device according to claim 9, wherein the connection is established through a film, the connection being between the surface opposite to the surface through which the semiconductor chip is mounted on the first substrate, or the portion of the conductive part, and the wiring layer of the second substrate.

13. The semiconductor device according to claim 10, wherein the wiring layer of the second substrate is a first wiring layer counting from the one surface of the second substrate.

14. The semiconductor device according to claim 7, wherein:
an electronic part is formed on the one surface of the second substrate; and
the surface opposite to the surface through which the semiconductor chip is mounted on the first substrate is distanced from the electronic part.

15. The semiconductor device according to claim 1, wherein:
the conductive part is a first conductive part; and
a second conductive part is provided at the other surface of the substrate or the first substrate.

16. The semiconductor device according to claim 15, wherein:
the substrate or the first substrate has a third conductive part passing therethrough in a thickness direction; and
the semiconductor chip and the second conductive part are connected through the third conductive part.

17. The semiconductor device according to claim 1, wherein:
the semiconductor chip is a first semiconductor chip; and
a second semiconductor chip or a semiconductor package including the second semiconductor chip is mounted on the other surface of the substrate or the first substrate.

18. The semiconductor device according to claim 17, wherein a center of the second semiconductor chip or the semiconductor package, in plan, is offset from a center of the first semiconductor chip.

19. A method for manufacturing a semiconductor device, comprising:
forming a conductive part on one surface of a substrate having a wiring layer in a manner that the conductive part is electrically insulated from the wiring layer;
mounting a semiconductor chip on the one surface of the substrate; and
forming external connection terminals on the one surface of the substrate, the external connection terminals having a melting point which is lower than that of the conductive part.

20. The method for manufacturing a semiconductor device according to claim 19, wherein:
the substrate is a first substrate; and
the method comprises mounting the first substrate of the semiconductor device so that one surface of the first substrate is located opposed to one surface of a second substrate.

21. The method for manufacturing a semiconductor device according to claim 20, wherein:
the second substrate has a wiring layer; and
the method comprises:
forming a recessed portion on a region of the one surface of the second substrate, the one surface being in contact with a surface opposite to the surface through which the semiconductor chip is mounted on the first substrate;
exposing the wiring layer in the recessed portion; and
connecting the surface opposite to the surface through which the semiconductor chip is mounted on the first substrate, to the exposed wiring layer.

22. The method for manufacturing a semiconductor device according to claim 20, wherein:
the second substrate has a wiring layer; and
the method comprises:
forming a recessed portion on a region of the one surface of the second substrate, the one surface being in contact with the conductive part;
exposing the wiring layer in the recessed portion; and
connecting a portion of the conductive part to the exposed wiring layer.

23. The method for manufacturing a semiconductor device according to claim 19, wherein:
the semiconductor chip is a first semiconductor chip; and
the method further comprises mounting a second semiconductor chip on the other surface of the substrate.

24. The method for manufacturing a semiconductor device according to claim 23, wherein, in the case where an area of the first semiconductor chip is different from that of the second semiconductor chip:
the method comprises mounting either one of the first and second semiconductor chips, whichever has a smaller area, and then mounting the other semiconductor chip.
